(19) United States
(12) Patent Application Publication
(10) Pub. No.: US 2026/0164638 A1
(43) Pub. Date: Jun. 11, 2026

(54) SEMICONDUCTOR DEVICE

(71) Applicant: SK hynix Inc., Gyeonggi-do (KR)

(72) Inventors: Se Hyun KIM, Gyeonggi-do (KR); Dong Jin KO, Gyeonggi-do (KR); Min Chul SUNG, Gyeonggi-do (KR)

(21) Appl. No.: 19/179,761

(22) Filed: Apr. 15, 2025

(30) Foreign Application Priority Data
Apr. 15, 2024 (KR) 10-2024-0050097

(51) Int. Cl. H10B 12/00

(52) U.S. Cl. CPC H10B 12/315

(57) ABSTRACT

A semiconductor device includes a bit line disposed to extend in a first direction; a first gate disposed to extend in a second direction intersecting with the first direction; a second gate disposed to extend in parallel with to the first gate; an active region having a first side contacting the bit line; and a contact disposed to contact a second side of the active region. The active region includes: a horizontal portion disposed to extend in the first direction; a vertical portion disposed between the first gate and the second gate; and a first contact region disposed to contact the contact and the vertical portion.

### CROSS-REFERENCE TO RELATED APPLICATION

This patent document claims the priority and benefits of Korean patent application No. 10-2024-0050097, filed on Apr. 15, 2024, the disclosure of which is incorporated herein by reference in its entirety as part of the disclosure of this patent document.

### TECHNICAL FIELD

Embodiments of the present disclosure generally relate to a semiconductor device, and more particularly to a semiconductor device including memory cells.

### BACKGROUND

As miniaturization and higher degree of integration of semiconductor devices have become major issues, memory cells included in semiconductor devices can be formed to have three-dimensional (3D) patterns. Miniaturized memory cells with three-dimensional (3D) patterns can be equipped with configurations that improve operation characteristics of the memory cells.

### SUMMARY

Various embodiments of the present disclosure relate to a semiconductor memory device with a higher degree of integration.

Various embodiments of the present disclosure relate to a semiconductor memory device in which contact resistance between an active region and an adjacent region is reduced.

In accordance with an embodiment of the present disclosure, a semiconductor device may include: a bit line disposed to extend in a first direction; a first gate disposed to extend in a second direction intersecting with the first direction; a second gate disposed to extend in parallel with the first gate; an active region having a first side contacting the bit line; and a contact disposed to contact a second side of the active region. The active region may include: a horizontal portion disposed to extend in the first direction; a vertical portion disposed between the first gate and the second gate; and a first contact region disposed to contact the contact and the vertical portion.

In some implementations, the bit line may be disposed to contact the horizontal portion.

In some implementations, the active region may further include a second contact region disposed between the bit line and the horizontal portion to contact the bit line and the horizontal portion.

In some implementations, the active region may include indium gallium zinc oxide (IGZO).

In some implementations, a width of the first contact region is equal to or larger than a width of the vertical portion.

In some implementations, a width of the first contact region is equal to or smaller than a width of the contact.

In some implementations, the active region may further include a first extension region disposed to contact a bottom surface of the first contact region and a side surface of the vertical portion.

In some implementations, the first contact region may be disposed to contact bottom and side surfaces of the contact.

In some implementations, the first contact region may be disposed along sidewalls and a bottom surface of a contact trench disposed in a contact insulation layer.

In some implementations, the contact trench may be disposed to overlap the vertical portion.

In some implementations, the contact may be connected to a capacitor.

In some implementations, the vertical portion may extend along a side surface of the first gate, and may form a first angle with respect to the horizontal portion.

In some implementations, the active region may further include a second extension region disposed over the horizontal portion.

In some implementations, the first gate and second gate may receive different control signals.

In accordance with another embodiment of the present disclosure, a semiconductor device may include: a bit line disposed to extend in a first direction; a first gate disposed to extend in a second direction intersecting with the first direction; one pair of second gates disposed at both sides of the first gate to extend in parallel with the first gate; an active region having a first side contacting the bit line; and a contact disposed to contact a second side of the active region. The active region may include: a horizontal portion disposed to extend in the first direction and contact the bit line; a vertical portion disposed between the first gate and the second gates to extend from the horizontal portion toward the contact; and a first contact region disposed between the contact and the vertical portion, wherein the horizontal portion is located below the second gates.

In some other implementations, the active region may further include: a second contact region disposed between the bit line and the horizontal portion to contact the bit line and the horizontal portion.

In some other implementations, the active region may include indium gallium zinc oxide (IGZO).

In some other implementations, the active region may further include a first extension region disposed to contact a bottom surface of the first contact region and a side surface of the vertical portion.

In some other implementations, the first extension region may be disposed to contact bottom and side surfaces of the contact.

In some other implementations, the active region may further include a second extension region disposed over the horizontal portion.

In accordance with yet another embodiment of the present disclosure, a semiconductor device may include: a bit line disposed to extend in a first direction; a first gate disposed to extend in a second direction intersecting with the first direction, wherein a cross-section of the first gate has a trapezoidal shape; one pair of second gates disposed at both sides of the first gate to extend in parallel with the first gate; and an active region including a horizontal portion contacting the bit line and a vertical portion disposed between the first gate and the pair of second gates to extend in a vertical direction.

It is to be understood that both the foregoing general description and the following detailed description of the present disclosure are illustrative and explanatory and are intended to provide further explanation of the disclosure as claimed.

### BRIEF DESCRIPTION OF THE DRAWINGS

The above and other features and beneficial aspects of the present disclosure will become readily apparent with reference to the following detailed description when considered in conjunction with the accompanying drawings.

FIG. 1 is a schematic perspective view illustrating an example of a semiconductor device according to embodiments of the present disclosure.

FIG. 2A is a cross-sectional view illustrating an example of the semiconductor device in which the center of a first gate is taken along a cutting line parallel to a second direction according to one embodiment of the present disclosure.

FIG. 2B is a cross-sectional view illustrating an example of the semiconductor device in which the center of a second gate is taken along a cutting line parallel to a second direction according to one embodiment of the present disclosure.

FIG. 2C is a cross-sectional view illustrating an example of the semiconductor device in which the center of a bit line is taken along a cutting line parallel to a first direction according to one embodiment of the present disclosure.

FIG. 3A is a cross-sectional view illustrating an example of the semiconductor device in which the center of a first gate is taken along a cutting line parallel to a second direction according to another embodiment of the present disclosure.

FIG. 3B is a cross-sectional view illustrating an example of the semiconductor device in which the center of a second gate is taken along a cutting line parallel to a second direction according to another embodiment of the present disclosure.

FIG. 3C is a cross-sectional view illustrating an example of the semiconductor device in which the center of a bit line is taken along a cutting line parallel to a first direction according to another embodiment of the present disclosure.

FIG. 4A is a cross-sectional view illustrating an example of the semiconductor device in which the center of a first gate is taken along a cutting line parallel to a second direction according to another embodiment of the present disclosure.

FIG. 4B is a cross-sectional view illustrating an example of the semiconductor device in which the center of a second gate is taken along a cutting line parallel to a second direction according to another embodiment of the present disclosure.

FIG. 4C is a cross-sectional view illustrating an example of the semiconductor device in which the center of a bit line is taken along a cutting line parallel to a first direction according to another embodiment of the present disclosure.

FIG. 5A is a cross-sectional view illustrating an example of the semiconductor device in which the center of a first gate is taken along a cutting line parallel to a second direction according to still another embodiment of the present disclosure.

FIG. 5B is a cross-sectional view illustrating an example of the semiconductor device in which the center of a second gate is taken along a cutting line parallel to a second direction according to still another embodiment of the present disclosure.

FIG. 5C is a cross-sectional view illustrating an example of the semiconductor device in which the center of a bit line is taken along a cutting line parallel to a first direction according to still another embodiment of the present disclosure.

### DETAILED DESCRIPTION

This patent document provides implementations and examples of a semiconductor device including memory cells that may be used in configurations to substantially address one or more technical or engineering issues and to mitigate limitations or disadvantages encountered in some other semiconductor devices. Some embodiments of the present disclosure relate to a semiconductor memory device with a higher degree of integration. Some embodiments of the present disclosure relate to a semiconductor memory device in which contact resistance between an active region and an adjacent region is reduced. In recognition of the issues above, the present disclosure may provide a semiconductor device that has three-dimensional (3D) channels to improve the degree of integration. The present disclosure may provide a semiconductor device that can reduce contact resistance between the active region and the bit line, and can reduce contact resistance between the active region and the capacitor.

Reference will now be made in detail to the embodiments of the present disclosure, examples of which are illustrated in the accompanying drawings. Wherever possible, the same reference numbers will be used throughout the drawings to refer to the same or like parts. While the disclosure is susceptible to various modifications and alternative forms, specific embodiments thereof are shown by way of example in the drawings. However, the disclosure should not be construed as being limited to the embodiments set forth herein.

Hereinafter, various embodiments will be described with reference to the accompanying drawings. However, the present disclosure is not limited to specific embodiments, but includes various modifications, equivalents and/or alternatives of the embodiments. The embodiments of the present disclosure may provide a variety of effects capable of being directly or indirectly recognized through the present disclosure.

In the following description, a detailed description of related known configurations or functions incorporated herein will be omitted to avoid obscuring the subject matter.

The terminology used herein is for the purpose of describing particular embodiments only and is not intended to be limiting of the present disclosure. As used herein, the singular forms are intended to include the plural forms as well, unless the context clearly indicates otherwise. It will be further understood that the terms “comprises”, “includes”, “including”, and/or “comprising,” when used in this specification, specify the presence of stated constituent elements, steps, operations, and/or components, but do not preclude the presence or addition of one or more other constituent elements, steps, operations, and/or components thereof. The term “and/or” may include a combination of a plurality of items or any one of a plurality of items.

Hereinafter, a semiconductor device and a method for manufacturing the same according to embodiments of the present disclosure will be described with reference to the attached drawings.

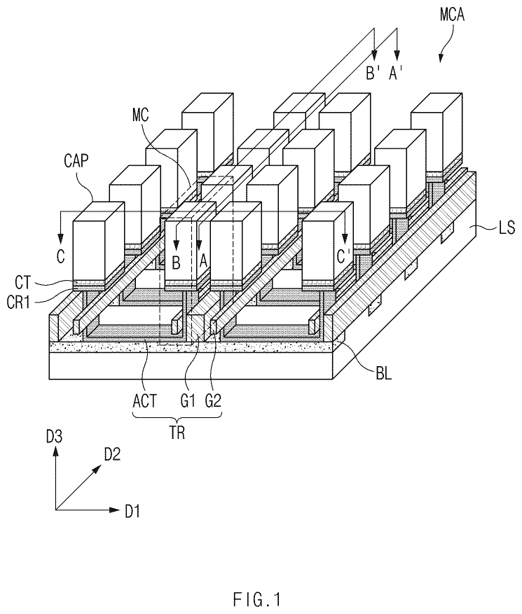

FIG. 1 is a schematic perspective view illustrating an example of a semiconductor device 1 according to embodiments of the present disclosure.

Referring to FIG. 1, the semiconductor device 1 may include a substrate (LS) and a memory cell array (MCA) formed over the substrate (LS). The memory cell array (MCA) may include a plurality of memory cells (MC) repeatedly arranged over the substrate (LS).

In some implementations, each memory cell may have a three-dimensional (3D) structure.

More specifically, each memory cell (MC) included in the memory cell array (MCA) may include a bit line (BL), a transistor (TR), a contact (CT), and a capacitor (CAP).

The bit line (BL) may be disposed over the substrate (LS), and may extend in a first direction (D1) parallel to one surface of the substrate (LS). Adjacent bit lines (BL) may be isolated from each other by an insulation layer (not shown).

The insulation layer may include, for example, silicon oxide, silicon nitride, or a combination thereof.

In some implementations, the capacitors (CAP) may be spaced apart from the bit line (BL) in a third direction (D3), and may be arranged in a matrix structure. Each capacitor (CAP) may be disposed over a contact (CT) that is located in a region where the gates (G1, G2) and the bit line (BL) overlap each other.

In some other implementations, each capacitor (CAP) may be arranged to deviate from the center of the contact (CT) located in a region where the gates (G1, G2) and the bit line (BL) overlap each other.

More specifically, the capacitors (CAP) may be arranged either in a zigzag shape or in a honeycomb shape with respect to the contacts (CTs) arranged in a matrix structure.

The transistor (TR) may be disposed between the bit line (BL) and the capacitor (CAP) in the third direction (D3).

The transistor (TR) may include at least a portion of the active region (ACT) connected to the bit line (BL), and may include a first gate (G1) and a second gate (G2).

According to the embodiment of FIG. 1, a word line driving voltage may be provided to the second gate (G2) extending in a second direction (D2) perpendicular to the first direction (D1). In other words, the second gate (G2) may operate as a word line of the transistor (TR).

In these instances, the first gate (G1) extending opposite to the second gate (G2) may be provided with a voltage different from that of the second gate (G2) to prevent interference between the second gates (G2) of the adjacent transistors (TR). For example, a ground voltage may be provided to the first gate (G1), and the first gate (G1) may operate as a back gate.

The first direction (D1) may be perpendicular to the second direction (D2), and the third direction (D3) may be perpendicular to each of the first direction (D1) and the second direction (D2).

Each memory cell (MC) may include a contact (CT) that electrically connects the capacitor (CAP) and the bit line (BL) to each other. The active region (ACT) may be in contact with the contact (CT) through a first contact region (CR1) located at one side of the vertical portion of the active region (ACT). For example, the contact (CT) may include a conductive material.

The active region (ACT) may include a channel region and source/drain regions of the transistor (TR).

The channel region may be formed in the active region (ACT) depending on the voltage applied to the second gate (G2) of the transistor (TR), and in these instances electrons may move between the source/drain regions through the channel region.

The active region (ACT) may include a horizontal portion extending in the first direction (D1) and a vertical portion extending in the third direction (D3).

Each memory cell (MC) may include one transistor (TR).

Two adjacent vertical portions included in the active region (ACT) may be connected to one horizontal portion. The horizontal portion included in the active region (ACT) may be connected to the bit line (BL).

An insulation layer may be formed between the active region ACT and the gates (G1, G2), and the active region (ACT) may be electrically isolated from the gates (G1, G2) by the insulation layer.

The memory cell array (MCA) may include a DRAM cell array. In some other implementations, the memory cell array (MCA) may include Phase Change Random Access Memory (PCRAM), Resistive Random Access Memory (ReRAM), Magnetic Random Access Memory (MRAM), etc.

The capacitor (CAP) may be replaced with another memory element depending on the type of memory cell array (MCA).

The substrate (LS) may be a material suitable for semiconductor processing. The substrate (LS) may include at least one of a conductive material, an insulation material (also called a dielectric material), and a semiconductor material (also called a semiconductive material). In some implementations, a plurality of material layers may be formed over the substrate (LS).

The substrate (LS) may include a semiconductor substrate. For example, the substrate (LS) may be formed of a semiconductor material containing silicon. The substrate (LS) may include silicon, monocrystalline silicon, amorphous silicon, silicon germanium, monocrystalline silicon germanium, polycrystalline silicon germanium, carbon-doped silicon, a combination thereof, or multilayers thereof.

The substrate (LS) may also include other semiconductor materials such as germanium. The substrate (LS) may include a group III/V semiconductor substrate, for example, a compound semiconductor substrate such as GaAs.

The substrate (LS) may include a silicon on insulator (SOI) substrate.

In another embodiment, the substrate (LS) may include a peripheral circuit region (not shown) located at a lower portion thereof. The peripheral circuit region may include a plurality of control circuits for controlling the memory cell array (MCA). At least one control circuit of the peripheral circuit region may include an N-channel transistor, a P-channel transistor, a CMOS circuit, or a combination thereof. At least one control circuit of the peripheral circuit region may include an address decoder circuit, a read circuit, a write circuit, etc.

At least one control circuit included in the peripheral circuit region may include a planar channel transistor, a recess channel transistor, a buried gate transistor, a fin channel transistor (FinFET), and the like.

At least one control circuit included in the peripheral circuit region may be electrically connected to the bit line (BL). The peripheral circuit region may include a sense amplifier (sense-amp), and the sense amplifier (sense-amp) may be electrically connected to the bit line (BL). Although not shown, a multi-level metal interconnection (MLM) may be disposed between the substrate (LS) and the memory cell array (MCA). The peripheral circuit region and the bit line (BL) may be connected to each other through the multi-level metal interconnection (MLM).

Referring again to FIG. 1, the bit lines (BL) may be disposed in the substrate (LS). In some implementations, an insulation layer may be disposed between the bit lines (BL) disposed in the substrate (LS) to electrically isolate adjacent bit lines (BL) from each other.

The bit lines (BL) may be laterally (or horizontally) oriented in the first direction (D1).

The bit lines (BL) may be referred to as laterally-oriented bit lines or laterally-extended bit lines.

The bit lines (BL) may include a conductive material. Each of the bit lines (BL) may include a silicon-based material, a metal-based material, or a combination thereof. Each of the bit lines (BL) may include polysilicon, metal, metal nitride, metal silicide, or a combination thereof.

The bit line (BL) may include polysilicon, titanium nitride, tungsten (W), or a combination thereof. For example, the bit line (BL) may include polysilicon doped with N-type impurities or titanium nitride (TiN).

The bit line (BL) may include a stacked structure (TiN/W) of titanium nitride (TiN) and tungsten (W). The bit line (BL) may further include an ohmic contact layer formed of, for example, a metal silicide.

Memory cells (MC) arranged horizontally in the first direction (D1) may share one bit line (BL). An insulation layer extending in the first direction (D1) may be provided between adjacent bit lines (BL). The insulation layer may include a plurality of layers and may function as a spacer to isolate adjacent bit lines (BL) from each other.

The transistors (TR) may be arranged in a matrix structure in the first direction (D1) and the second direction (D2).

Each of transistors (TR) may be disposed between the bit line (BL) and the capacitor (CAP).

The transistor (TR) may include an active region (ACT), an insulation layer (not shown), and gates (G1, G2).

The gates (G1, G2) may extend in the second direction (D2), and the active region (ACT) may include a horizontal portion extending in the first direction (D1) and a vertical portion extending in the third direction (D3).

In some implementations, the vertical portion may extend in a third direction (D3) perpendicular to each of the first direction (D1) and the second direction (D2).

The active region (ACT) may include a first contact region (CR1) that contacts one side of the vertical portion and is located between the vertical portion and the capacitor (CAP).

The insulation layer may be disposed to isolate adjacent active regions (ACT) and the gates (G1, G2) from each other.

Each of the gates (G1, G2) may include a metal, a metal mixture, a metal alloy, titanium nitride, tungsten, polysilicon, or a combination thereof.

For example, the gates (G1, G2) may include a stacked structure (TiN/W) in which titanium nitride and tungsten are sequentially stacked.

The gates (G1, G2) may extend in one direction, and the bit line (BL) may extend in the other direction perpendicular to the one direction. The active region (ACT) may include a semiconductor material or an oxide semiconductor material.

The bit line (BL) may be electrically isolated from the gates (G1, G2) by an insulation layer. In other words, the insulation layer may be disposed between the bit line (BL) and the gates (G1, G2).

The active region (ACT) may include a plurality of impurity regions. The impurity regions may include source/drain regions of the transistor (TR).

The active region (ACT) may include doped polysilicon, undoped polysilicon, amorphous silicon, IGZO (amorphous indium gallium zinc oxide semiconductor), indium zinc oxide (IZO), indium tin oxide (ITO), indium oxide (InO₃), and the like.

The horizontal portion included in the active region (ACT) may be electrically connected to the bit line (BL).

The capacitor (CAP) may be connected to the first contact region (CR1) included in the active region (ACT) through the contact (CT).

In addition, the insulation layer may be disposed between the gates (G1, G2), and the gates (G1, G2) may be electrically isolated from each other by the insulation layer.

The insulation layer may include, for example, silicon oxide, silicon nitride, and the like. There may be a difference in composition between the insulation layers according to locations of the insulation layers.

The capacitor (CAP) may have a shape that extends vertically from one surface of the substrate (LS), and may be arranged to contact the first contact region (CR1) included in the active region (ACT) through the contact (CT). The capacitor (CAP) may include, for example, a metal-insulator-metal (MIM) capacitor.

The capacitor (CAP) implemented as the MIM capacitor may include two poles and a dielectric layer disposed between the two poles. The dielectric layer may include silicon oxide, silicon nitride, a high-k material (e.g., hafnium oxide or aluminum oxide, etc.), or a combination thereof.

The high-k material may have a higher dielectric constant than silicon oxide (SiO₂). Silicon oxide (SiO₂) may have a dielectric constant of about 3.9, and the dielectric layer may include a high-k material with a dielectric constant of 4 or more. For example, the high-k material may have a dielectric constant of about 20 or more.

The high-k material may include hafnium oxide (HfO₂), zirconium oxide (ZrO₂), aluminum oxide (Al₂O₃), lanthanum oxide (La₂O₃), titanium oxide (TiO₂), tantalum oxide (Ta₂O₅), niobium oxide (Nb₂O₅), or strontium titanium oxide (SrTiO₃) and the like. In another embodiment, the dielectric layer may include a composite layer including two or more layers formed of the above-mentioned high-k material.

The dielectric layer may include a stacked structure of a high-k material and a high bandgap material that has a larger band gap than the high-k material. For example, the dielectric layer may include silicon oxide (SiO₂) as another high bandgap material in addition to aluminum oxide (Al₂O₃). Leakage current may be suppressed by the dielectric layer containing a high bandgap material.

The dielectric layer may include a laminated structure in which high-k materials and high bandgap materials are alternately stacked. For example, the laminated structure may include ZAZA (ZrO₂/Al₂O₃/ZrO₂/Al₂O₃), ZAZAZ (ZrO₂/Al₂O₃/ZrO₂/Al₂O₃/ZrO₂), HAHA (HfO₂/Al₂O₃/HfO₂/Al₂O₃) or HAHAH (HfO₂/Al₂O₃/HfO₂/Al₂O₃/HfO₂).

An anode included in the capacitor (CAP) may include a metal, a noble metal, a metal nitride, a conductive metal oxide, a conductive noble metal oxide, a metal carbide, a metal silicide, or a combination thereof. For example, the anode included in the capacitor (CAP) may include titanium (Ti), titanium nitride (TiN), tantalum (Ta), tantalum nitride (TaN), tungsten (W), tungsten nitride (WN), ruthenium (Ru), ruthenium oxide (RuO₂), iridium (Ir), iridium oxide (IrO₂), platinum (Pt), molybdenum (Mo), molybdenum oxide (MoO), a titanium nitride/tungsten (TiN/W) stack, and a tungsten nitride/tungsten (WN/W) stack.

In another embodiment, the poles of the capacitor (CAP) may include a combination of a metal-based material and a silicon-based material. For example, the combination of a metal-based material and a silicon-based material may be a stacked structure of titanium nitride/silicon germanium/tungsten nitride (TiN/SiGe/WN).

The capacitor (CAP) may have a three-dimensional (3D) structure, and the three-dimensional capacitors (CAP) may be repeatedly arranged in a matrix shape on one surface of the substrate (LS). The three-dimensional (3D) structure may be, for example, a cylindrical shape, a pillar shape, or a pylinder shape. Here, the pylinder shape may refer to a structure in which the pillar shape and the cylindrical shape are merged.

In another embodiment, the capacitor (CAP) may have a structure that is obliquely arranged with respect to a contact (CT) located in a region in which the bit line (BL) and the gates (G1, G2) are arranged to overlap each other so that the largest number of capacitors (CAP) can be arranged in the same area.

The memory cells (MC) may share the first gate (G1) and the second gate (G2). The first gate (G1) and the second gate (G2) may include the same conductive material.

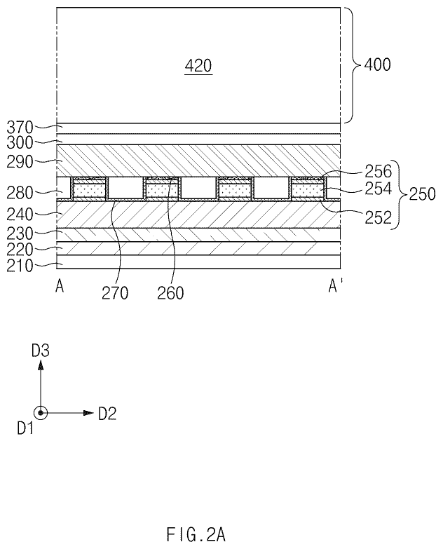

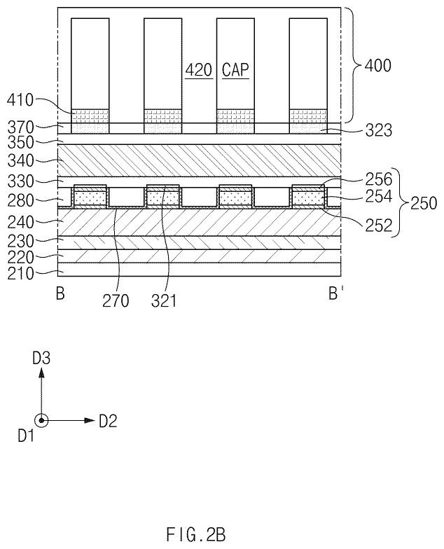

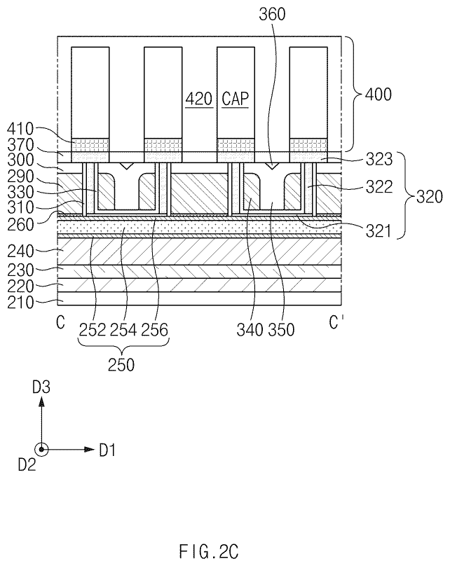

FIG. 2A is a cross-sectional view illustrating the center of the first gate G1 taken along a cutting line (A-A′ of FIG. 1) parallel to the second direction (D2) according to an embodiment of the present disclosure. FIG. 2B is a cross-sectional view illustrating the center of the second gate (G2) taken along a cutting line (B-B′ of FIG. 1) parallel to the second direction (D2) according to an embodiment of the present disclosure. FIG. 2C is a cross-sectional view illustrating the center of the bit line (BL) taken along a cutting line (C-C′ of FIG. 1) parallel to the first direction (D1) according to an embodiment of the present disclosure.

Referring to FIGS. 2A, 2B, and 2C, a substrate layer 210, a silicide layer 220 formed over the substrate layer 210, and a first nitride layer 230 formed over the silicide layer 220 are illustrated.

The substrate layer 210 may include a silicon semiconductor material. For example, the substrate layer 210 may include silicon, monocrystalline silicon, polysilicon, amorphous silicon, silicon germanium, monocrystalline silicon germanium, polycrystalline silicon germanium, carbon-doped silicon, etc.

The substrate layer 210 may include a plurality of control circuits configured to control the operation of the semiconductor device, and a region where the control circuits are provided may be referred to as a peripheral circuit region.

The silicide layer 220 formed over the substrate layer 210 may include a metal silicide material such as cobalt silicide (CoSi). The silicide layer 220 is provided in the semiconductor device, so that the operation resistance of the semiconductor device may decrease. In addition, the silicide layer 220 may serve as a protective layer for the substrate layer 210, and may thus prevent damage to the substrate layer 210 during a semiconductor fabrication process.

The first nitride layer 230 formed over the silicide layer 220 may refer to a layer containing silicon nitride. Since the first nitride layer 230 includes silicon nitride, damage to the substrate layer 210 may be prevented during a high-temperature semiconductor fabrication process.

Referring to FIGS. 2A, 2B and 2C, the first oxide layer 240 may be disposed over the first nitride layer 230. The first oxide layer 240 may be a layer containing silicon oxide, etc., and may operate as an insulation layer together with the first nitride layer 230.

As the first nitride layer 230 and the first oxide layer 240 are provided in the semiconductor device, the control circuits included in the substrate layer 210 can be electrically isolated from the bit line 250.

The bit line 250 disposed over the first oxide layer 240 may include a plurality of layers extending in the first direction (D1). For example, the bit line 250 may include a first bit-line layer 252 containing titanium nitride (TiN), a second bit-line layer 254 containing tungsten (W), and a third bit-line layer 256 containing titanium nitride (TiN).

Since materials of a plurality of layers included in the bit line 250 are adjusted, resistance of the semiconductor device may also be adjusted.

The first bit-line layer 252 and the third bit-line layer 256 included in the bit line 250 may prevent the second bit-line layer 254 from being oxidized by exposure to oxygen. When the second bit-line layer 254 is exposed to oxygen, tungsten (W) may be oxidized, thereby causing disconnection and defects.

In addition, titanium nitride (TiN) included in the first bit-line layer 252 may have a higher adhesion to silicon oxide than tungsten (W), and the first bit-line layer 252 is disposed between the first oxide layer 240 and the second bit-line layer 254, resulting in improvement in the interfacial stability of the bit lines 250.

After depositing the plurality of layers, the bit lines 250 may be formed through an etching process that uses a mask.

The adjacent bit lines 250 may be electrically isolated from each other by a second bit-line isolation layer 270 and a third bit-line isolation layer 280. In some implementations, the second bit-line isolation layer 270 may include silicon nitride, and the third bit-line isolation layer 280 may include silicon oxide.

The bit lines 250 and the first gate 290 may be isolated from each other by a first bit-line isolation layer 260.

The second bit-line isolation layer 270 and the third bit-line isolation layer 280 may function as spacers that electrically isolate the adjacent bit lines 250 from each other.

The first bit-line isolation layer 260 may be disposed over each bit line 250 to electrically isolate the bit line 250 from the first gate 290. The first bit-line isolation layer 260 may include silicon oxide (SiCO) containing carbon.

Referring to FIGS. 2B and 2C, an active region 320 electrically connected to at least a portion of the bit lines 250 may be disposed over the bit lines 250. The active region 320 may be electrically isolated from the second gate 340 by the second gate oxide layer 330.

The first gate 290 and the second gate 340 may include a metal, a metal mixture, a metal alloy, titanium nitride, tungsten, polysilicon, or a combination thereof. For example, the first gate 290 and the second gate 340 may include titanium nitride.

Referring to FIG. 2C, the first gate oxide 310 may be disposed not only over the first bit-line isolation layer 260, but also at sidewalls of the first gate 290. Although not shown in FIGS. 2A to 2C, at least a portion of the first gate oxide 310 may be disposed over the third bit-line isolation layer 280.

The first gate oxide 310 may be disposed between the first gate 290 and the active region 320. The first gate oxide 310 may include an insulation material such as silicon oxide.

A second nitride layer 300 may be provided over the first gate 290.

A third nitride layer 350 may be disposed between adjacent second gates 340. In addition, a third nitride layer 350 may be disposed between the first contact region 323 and the second gates 340.

The first contact region 323 may be formed by selectively etching at least a portion of the contact insulation layer 370 and depositing the same material as the active region 320. For example, the first contact region 323 may be a region containing an oxide semiconductor material.

A second oxide layer 360 may be disposed over the third nitride layer 350 located between the second gates 340. Vertical contact portions to which the second gate 340 and the conductive lines are connected may be formed using a difference in etch rate between the second oxide layer 360 and the third nitride layer 350.

The active region 320 may include a horizontal portion 321 formed to contact the bit line 250, and a vertical portion formed to extend in the vertical direction (D3) while being disposed between the first gate 290 and the second gate 340.

The active region 320 may include a first contact region 323 that is located at one side of the vertical portion 322 and is in contact with the contact 410.

The active region 320 may include, for example, an oxide semiconductor material, and the oxide semiconductor material may include indium gallium zinc oxide (IGZO).

In another embodiment, the active region 320 may include doped polysilicon, undoped polysilicon, amorphous silicon, indium zinc oxide (IZO), indium tin oxide (ITO), indium oxide (InO₃), and the like.

Since IGZO has low leakage current characteristics and the active region 320 is formed of IGZO, a semiconductor device with low standby power can be implemented.

In addition, since the active region 320 includes IGZO, fabrication process difficulty may be reduced, and the active region 320 with a three-dimensional (3D) structure including horizontal and vertical portions 321 and 322 may be easily formed.

The first contact region 323 may include the same material as the active region 320 to reduce contact resistance between the oxide semiconductor material contacts 410 included in the active region 320.

The first contact region 323 may have a larger width than the vertical portion in the first direction (D1). The width of the first contact region 323 may be the same as the width of the contact 410.

Since the first contact region 323 has a larger width than the vertical portion 322, a contact area between the contact 410 and the first contact region 323 can be secured, thereby guaranteeing contact stability between the contact 410 and the first contact region 323.

The contact 410 formed over the first contact region 323 may include a metal, a metal silicide, or a metal nitride. At least a portion of the capacitor (CAP) disposed over the contact 410 may be arranged to overlap the contact 410.

The contact insulation layer 370 may be disposed between adjacent first contact regions 323. The contact insulation layer 370 may be provided to surround the first contact region 323. In other words, the contact insulation layer 370 may be disposed between adjacent first contact regions 323.

A layer where the capacitor (CAP) is disposed may be referred to as a capacitor layer 400.

The capacitor layer 400 may include at least a portion of the contacts 410, capacitors (CAPs) formed to overlap upper portions of the contacts 410, and a capacitor insulation layer 420 disposed between the capacitors (CAPs) and the contacts 410.

Each capacitor (CAP) may operate as a data storage unit for writing or reading data according to a control signal applied to the semiconductor device.

Each capacitor (CAP) may include a capacitor dielectric layer and a plurality of storage electrodes. Depending on the control signal provided to the first gates 290 and the second gates 340, a determination of whether a voltage is being provided to the capacitor (CAP) may be made, and the magnitude of a voltage provided to the capacitor (CAP) may also be determined. The semiconductor device may read out stored data based on a signal corresponding to the voltage of the capacitor (CAP).

The capacitor (CAP) may have a shape extending in the vertical direction (i.e., the third direction D3) with respect to the substrate layer 210 within the capacitor layer 400. More specifically, the capacitor (CAP) may be formed in a cylindrical or pillar shape. As the capacitor (CAP) has a cylindrical or pillar shape, the capacitor (CAP) density can increase within the same area. As the density of the capacitor (CAP) increases, the data storage capacity of the semiconductor device may increase.

Each capacitor (CAP) may correspond to one contact 410, and one contact 410 may contact one capacitor (CAP).

Referring to the semiconductor device according to the embodiments of FIGS. 2A to 2C, a ground voltage may be provided to the first gate 290 at data read/write time points, and a word line driving voltage may be provided to the second gate 340 at data read/write time points. When a ground voltage is provided to the first gate 290, the first gate 290 may provide a back-bias voltage to the semiconductor device.

The first gate 290 may be disposed between two adjacent second gates 340 (for example, between a pair of second gates 340 disposed parallel to the first gate 290). As a ground voltage is provided to the first gate 290, adjacent second gates 340 may be electrically isolated from each other.

Such electrical isolation between the adjacent second gates 340 may mean that electrical interference between the adjacent second gates 340 is blocked.

As the semiconductor device is reduced in size, the distance between the second gates 340 may become shorter. When the distance between the second gates 340 is shortened, a coupling phenomenon may occur between the adjacent second gates 340 due to a word line driving voltage provided to each of the second gates 340. Due to the coupling phenomenon, unexpected errors may occur during data read/write operations of the semiconductor device.

In some implementations, the first gate 290 is disposed between the second gates 340 and the ground voltage is provided to the first gate 290, so that the coupling phenomenon between the second gates 340 is prevented, thereby improving the operation characteristics of the semiconductor device. In addition, since a ground voltage is provided to the first gate 290, the coupling phenomenon between adjacent active regions 320 can be prevented during operation of the semiconductor device.

In addition, the first gate 290 provided with a ground voltage may provide a back-bias voltage to the semiconductor device, thereby efficiently suppressing leakage current (e.g., gate induced drain leakage (GIDL), etc.) and improving electrical characteristics of the semiconductor device. In addition, the first gate 290 may control threshold voltage characteristics of the semiconductor device by providing a back-bias voltage to the semiconductor device.

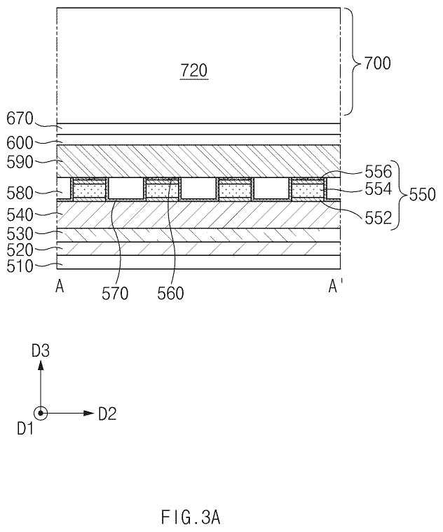

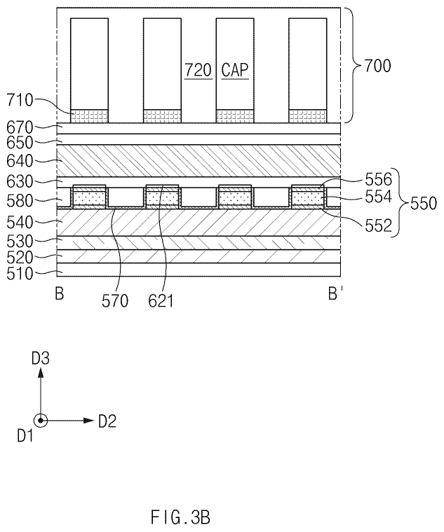

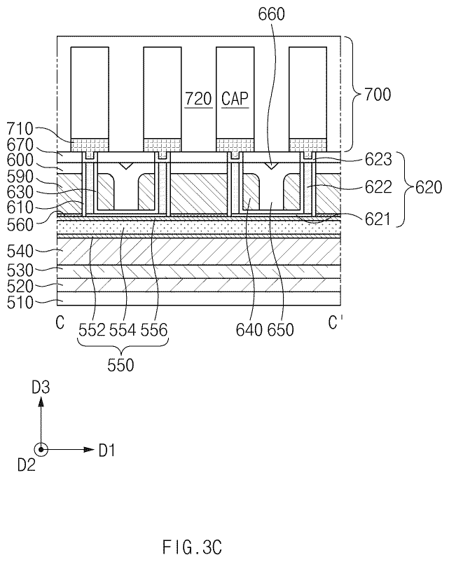

FIG. 3A is a cross-sectional view illustrating the center of the first gate G1 taken along a cutting line (A-A′ of FIG. 1) parallel to the second direction (D2) according to another embodiment of the present disclosure. FIG. 3B is a cross-sectional view illustrating the center of the second gate (G2) taken along a cutting line (B-B′ of FIG. 1) parallel to the second direction (D2) according to another embodiment of the present disclosure. FIG. 3C is a cross-sectional view illustrating the center of the bit line (BL) taken along a cutting line (C-C′ of FIG. 1) parallel to the first direction (D1) according to another embodiment of the present disclosure.

Only the first contact regions 623 included in the active region 620, the contact insulation layer 670 for electrically isolating the first contact regions 623 from each other, and the contacts 710 according to the embodiments of FIGS. 3A to 3C are different from those of the embodiments of FIGS. 2A to 2C, and as such redundant description thereof will herein be omitted for brevity, such that the embodiments of FIGS. 3A to 3C will hereinafter be described centering upon characteristics different from those of the embodiments of FIGS. 2A to 2C.

Referring to FIGS. 3A, 3B, and 3C, a substrate layer 510, a silicide layer 520 formed over the substrate layer 510, and a first nitride layer 530 formed over the silicide layer 520 are illustrated. Additionally, a first oxide layer 540 may be disposed over the first nitride layer 530, and a bit line 550 may be disposed over the first oxide layer 540.

The bit line 550 may include a plurality of layers extending in the first direction (D1). For example, the bit line 550 may include a first bit-line layer 552 containing titanium nitride (TiN), a second bit-line layer 554 containing tungsten (W), and a third bit-line layer 556 containing titanium nitride (TiN).

A second bit-line isolation layer 570 and a third bit-line isolation layer 580 may be disposed between adjacent bit lines 550. In some implementations, the second bit-line isolation layer 570 may include silicon nitride, and the third bit-line isolation layer 580 may include silicon oxide.

The first bit-line isolation layer 560 may be disposed over each bit line 550 to electrically isolate the bit lines 550 from the first gates 590. The first bit-line isolation layer 560 may include silicon oxide (SiCO) containing carbon.

Referring to FIGS. 3B and 3C, an active region 620 electrically connected to at least a portion of the bit lines 550 may be disposed over the bit lines 550. The second gate oxide layer 630 may be disposed between the active region 620 and the second gates 640.

The first gates 590 and the second gates 640 may include a metal, a metal mixture, a metal alloy, titanium nitride, tungsten, polysilicon, or a combination thereof. For example, the first gates 590 and the second gates 640 may include titanium nitride.

Referring to FIG. 3C, the first gate oxide 610 may be disposed not only over the first bit-line isolation layer 560, but also at sidewalls of the first gate 590.

The first gate oxide 610 may be disposed between the first gate 590 and the active region 620. The first gate oxide 610 may include an insulation material such as silicon oxide.

A second nitride layer 600 may be disposed between the contact insulation layer 670 and the first gate 590.

A third nitride layer 650 may be disposed between adjacent second gates 640. Additionally, a third nitride layer 650 may be disposed between the contact insulation layer 670 and the second gates 640.

A second oxide layer 660 may be disposed over the third nitride layer 650 located between the second gates 640. Contact portions to which the second gates 640 and the conductive lines are connected may be formed in the second gates 640 using a difference in etch rate between the second oxide layer 660 and the third nitride layer 650.

The active region 620 may include a horizontal portion 621 formed to contact the bit line 550, and a vertical portion 622 formed to extend in the vertical direction (D3) while being disposed between the first gate 590 and the second gate 640. The active region 620 may include, for example, an oxide semiconductor material.

The active region 620 may include a first contact region 623 that contacts one end of the vertical portion 622 and is connected to the contact 710.

The first contact region 623 according to another embodiment of the present disclosure may be formed to surround the sidewalls and bottom surface of the contact trench formed in the contact insulation layer 670. The contact trench may overlap the vertical portion 622 of the active region 620.

In some implementations, the contact trench may be formed in a trapezoidal shape in which the length of the upper side is longer than the length of the bottom side. In this case, the sidewalls of the contact trench may have an inclined shape.

Additionally, at least a portion of the contact 710 that contacts the first contact region 623 may be recessed into the first contact region 623. Accordingly, the first contact region 623 may contact the bottom and side surfaces of the contact 710.

The first contact region 623 is in contact with the bottom and side surfaces of the contact 710, and the contact 710 has a shape that is recessed into the first contact region 623, so that contact stability between the first contact region 623 and the contact 710 can be secured.

The contact 710 may include a metal, a metal silicide, or a metal nitride. At least a portion of the capacitor (CAP) disposed over the contact 710 may be arranged to overlap the contact 710.

The contact insulation layer 670 may be disposed between adjacent first contact regions 623.

A layer where the capacitor (CAP) is disposed may be referred to as the capacitor layer 700.

The capacitor layer 700 may include at least a portion of the contacts 710, and may include capacitors (CAP) and a capacitor insulation layer 720 disposed between the capacitors (CAP).

Each capacitor (CAP) may have a shape extending in a direction (i.e., a third direction D3) perpendicular to the substrate layer 510 within the capacitor layer 700. More specifically, the capacitor (CAP) may be formed in a cylindrical shape or a pillar shape.

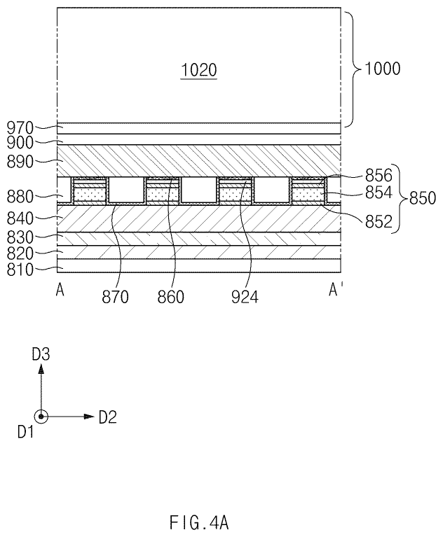

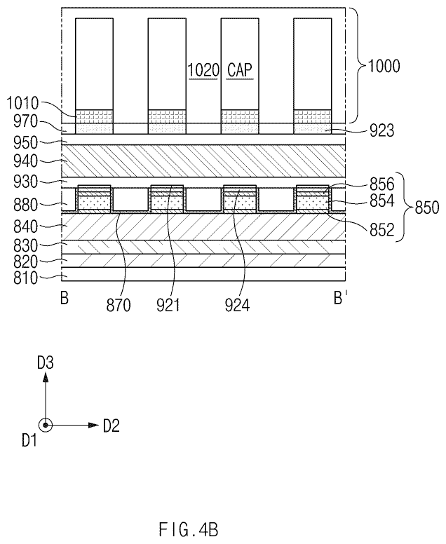

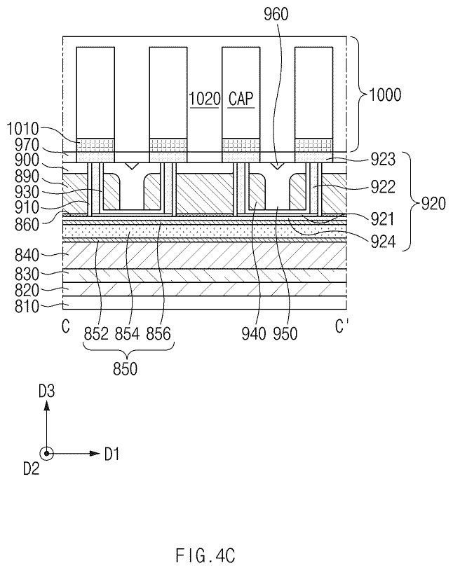

FIG. 4A is a cross-sectional view illustrating the center of the first gate G1 taken along a cutting line (A-A′ of FIG. 1) parallel to the second direction (D2) according to another embodiment of the present disclosure. FIG. 4B is a cross-sectional view illustrating the center of the second gate (G2) taken along a cutting line (B-B′ of FIG. 1) parallel to the second direction (D2) according to another embodiment of the present disclosure. FIG. 4C is a cross-sectional view illustrating the center of the bit line (BL) taken along a cutting line (C-C′ of FIG. 1) parallel to the first direction (D1) according to another embodiment of the present disclosure.

Only the second contact regions 924 included in the active region 920 according to the embodiments of FIGS. 4A to 4C are different from those of the embodiments of FIGS. 2A to 2C, and as such redundant description thereof will herein be omitted for brevity, such that the embodiments of FIGS. 4A to 4C will hereinafter be described centering upon characteristics different from those of the embodiments of FIGS. 2A to 2C.

Referring to FIGS. 4A, 4B, and 4C, a substrate layer 810, a silicide layer 820 formed over the substrate layer 810, and a first nitride layer 830 formed over the silicide layer 820 are illustrated. Additionally, a first oxide layer 840 may be disposed over the first nitride layer 830, and a bit line 850 may be disposed over the first oxide layer 840.

The bit line 850 may include a plurality of layers extending in the first direction (D1). For example, the bit line 850 may include a first bit-line layer 852 containing titanium nitride (TiN), a second bit-line layer 854 containing tungsten (W), and a third bit-line layer 856 containing titanium nitride (TiN).

A second contact region 924 may be disposed over the bit line 850. The second contact region 924 may extend in the direction (D1) in which the bit line 850 extends.

The second contact region 924 may be included in the active region 920, and may include the same material as the active region 920.

The second contact region 924 may extend along the horizontal portion 921 included in the active region 920, and may be electrically isolated from the first gate 890 by the first bit-line isolation layer 860 and the first gate oxide 910.

Since the second contact region 924 includes the same material as the active region 920, contact resistance between the active region 920 and the bit line 850 may be reduced. Additionally, since the second contact region 924 has been formed, the active region 920 can be expanded.

A second bit-line isolation layer 870 and a third bit-line isolation layer 880 may be disposed between adjacent bit lines 850. In some implementations, the second bit-line isolation layer 870 may include silicon nitride, and the third bit-line isolation layer 880 may include silicon oxide.

The second bit-line isolation layer 870 may be in contact with the second contact region 924. Additionally, the second bit-line isolation layer 870 may be in contact with the first bit-line isolation layer 860.

The second bit-line isolation layer 870 may have a shape in contact with the second contact region 924. In addition, the second bit-line isolation layer 870 may be in contact with the first bit-line isolation layer 860.

In other words, after the second contact region 924 is formed over the bit line 850 and the first bit-line isolation layer 860 is formed over the second contact region 924, the second bit-line isolation layer 870 may be formed along the side surfaces of the bit line 850, and the second contact region 924.

The first bit-line isolation layer 860 may be disposed between the first gate 890 and the second contact region 924. The first bit-line isolation layer 860 may include silicon oxide (SiCO) containing carbon.

The active region 920 formed over the bit line 850 may be in contact with the bit line 850 through the second contact region 924.

A second gate oxide 930 may be disposed between the active region 920 and the second gate 940.

The first gates 890 and the second gates 940 may include a metal, a metal mixture, a metal alloy, titanium nitride, tungsten, polysilicon, or a combination thereof. For example, the first gates 890 and the second gates 940 may include titanium nitride.

Referring to FIG. 4C, the first gate oxide 910 may be disposed not only over the first bit-line isolation layer 860, but also at sidewalls of the first gate 890.

The first gate oxide 910 may be disposed between the first gate 890 and the active region 920. The first gate oxide 910 may include an insulation material such as silicon oxide.

A second nitride layer 900 may be disposed between the contact insulation layer 970 and the first gate 890.

A third nitride layer 950 may be disposed between adjacent second gates 940. Additionally, a third nitride layer 950 may be disposed between the contact insulation layer 670 and the second gates 940.

A second oxide layer 960 may be disposed over the third nitride layer 950 located between the second gates 940. Contact portions to which the second gates 940 and the conductive lines are connected may be formed in the second gates 940 using a difference in etch rate between the second oxide layer 960 and the third nitride layer 950.

The active region 920 may include a horizontal portion 921 formed to contact the bit line 850, and a vertical portion 922 formed to extend in the vertical direction (D3) while being disposed between the first gate 890 and the second gate 940. The active region 920 may include, for example, an oxide semiconductor material.

One end of the vertical portion 922 included in the active region 920 may include a first contact region 923 connected to the contact 1010.

The contact 1010 may include a metal, a metal silicide, or a metal nitride. At least a portion of the capacitor (CAP) disposed over the contact 1010 may be arranged to overlap the contact 1010.

The contact insulation layer 970 may be disposed between adjacent first contact regions 923.

A layer where the capacitor (CAP) is disposed may be referred to as the capacitor layer 1000.

The capacitor layer 1000 may include at least a portion of the contacts 1010, and may include capacitors (CAP) and a capacitor insulation layer 1020 disposed between the capacitors (CAP).

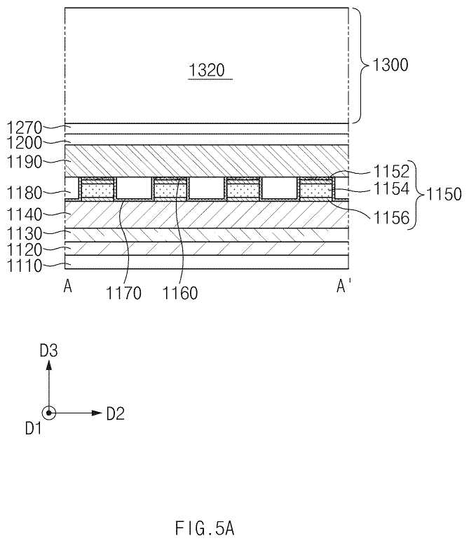

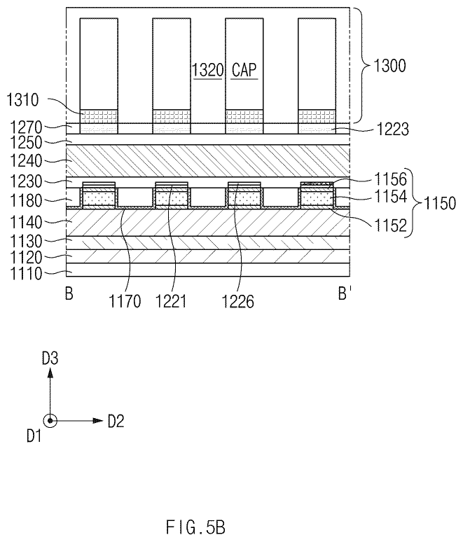

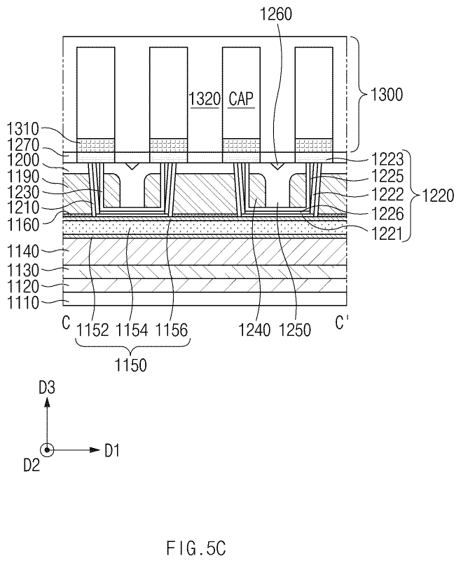

FIG. 5A is a cross-sectional view illustrating the center of the first gate G1 taken along a cutting line (A-A′ of FIG. 1) parallel to the second direction (D2) according to another embodiment of the present disclosure. FIG. 5B is a cross-sectional view illustrating the center of the second gate (G2) taken along a cutting line (B-B′ of FIG. 1) parallel to the second direction (D2) according to the embodiment of FIG. 5A. FIG. 5C is a cross-sectional view illustrating the center of the bit line (BL) taken along a cutting line (C-C′ of FIG. 1) parallel to the first direction (D1) according to the embodiment of FIGS. 5A and 5B.

Only the shape of the active region 1220, and the first extension region 1225 and the second extension regions 1226 included in the active region 1220 according to the embodiments of FIGS. 5A to 5C are different from those of the embodiments of FIGS. 2A to 2C, and as such redundant description thereof will herein be omitted for brevity, such that the embodiments of FIGS. 5A to 5C will hereinafter be described centering upon characteristics different from those of the embodiments of FIGS. 2A to 2C.

Referring to FIGS. 5A, 5B, and 5C, a substrate layer 1110, a silicide layer 1120 formed over the substrate layer 1110, and a first nitride layer 1130 formed over the silicide layer 1120 are illustrated. Additionally, a first oxide layer 1140 may be disposed over the first nitride layer 1130, and a bit line 1150 may be disposed over the first oxide layer 1140.

The bit line 1150 may include a plurality of layers extending in the first direction (D1). For example, the bit line 1150 may include a first bit-line layer 1152 containing titanium nitride (TiN), a second bit-line layer 1154 containing tungsten (W), and a third bit-line layer 1156 containing titanium nitride (TiN).

An active region 1220 may be disposed over the bit line 1150.

A horizontal portion 1221 included in the active region 1220 may be connected to the bit line 1150, and a first bit-line isolation layer 1160 and a first gate oxide 1210 may be disposed between the active region 1220 and the first gate 890.

The active region 1220 may include a horizontal portion 1221 formed to contact the bit line 1150, and a vertical portion 1222 formed to extend in the vertical direction (D3) while being disposed between the first gate 1190 and the second gate 1240. The active region 1220 may include, for example, an oxide semiconductor material.

Referring to FIG. 5C, the cross-section of the first gate 1190 according to an embodiment of the present disclosure may have a trapezoidal shape. More specifically, the first gate 1190 may have a rectangular shape in which the width of an upper portion is smaller than the width of a lower portion.

In some implementations, when forming the first gate 1190, the side surface of the first gate 1190 is etched to create a slope, so that the first gate 1190 may have a trapezoidal cross-section.

The vertical portion 1222 included in the active region 1220 may be formed diagonally along the first gate oxide 1210 disposed on a side surface of the first gate 1190. The vertical portion 1222 may be formed to form a preset first angle with respect to the horizontal portion 1221. In some implementations, the first angle may be greater than 90 degrees and less than 180 degrees.

The vertical portion 1222 may be formed obliquely to form a first angle with respect to the horizontal portion 1221, so that the vertical portion 1222 may extend along the sidewalls of the first gate 1190.

The active region 1220 may include a first extension region 1225 disposed on a side surface of the vertical portion 1222.

Additionally, the active region 1220 may include a vertical portion 1222 and a first contact region 1223 disposed over the first extension region 1225.

The first extension region 1225 and the first contact region 1223 may include an oxide semiconductor material such as amorphous indium gallium zinc oxide (IGZO).

As the first extension region 1225 is disposed on the side surface of the vertical portion 1222, the contact area between the vertical portion 1222 and the first contact region 1223 may be expanded.

The active region 1220 may include a second extension region 1226 disposed over the horizontal portion 1221. The second extension region 1226 may include the same oxide semiconductor material as the active region 1220. As the second extension region 1226 is formed, the active region 1220 can be expanded.

In some implementations, the first extension region 1225 and the second extension region 1226 may be formed through a sputtering process.

More specifically, after an oxide semiconductor layer that serves as the horizontal portion 1221 and the vertical portion 1222 is deposited on the first gate oxide 1210, an oxide semiconductor material to be used as the first extension region 1225 and the second extension region 1226 through the sputtering process can be selectively deposited.

A second bit-line isolation layer 1170 and a third bit-line isolation layer 1180 may be disposed between adjacent bit lines 1150. In some implementations, the second bit-line isolation layer 1170 may include silicon nitride, and the third bit-line isolation layer 1180 may include silicon oxide.

The first bit-line isolation layer 1160 may be disposed between the first gate 1190 and the bit line 1150. The first bit-line isolation layer 1160 may include silicon oxide (SiCO) containing carbon.

A second gate oxide 1230 may be disposed between the active region 1220 and the second gate 1240.

The first gate 1190 and the second gate 1240 may include a metal, a metal mixture, a metal alloy, titanium nitride, tungsten, polysilicon, or a combination thereof. For example, the first gate 1190 and the second gate 1240 may include titanium nitride.

Referring to FIG. 5C, the first gate oxide 1210 may be disposed not only over the first bit-line isolation layer 1160, but also at sidewalls of the first gate 1190.

The first gate oxide 1210 may be disposed between the first gate 1190 and the active region 1220. The first gate oxide 1210 may include an insulation material such as silicon oxide.

A second nitride layer 1200 may be disposed between the first gate 1190 and the contact insulation layer 1270.

A third nitride layer 1250 may be disposed between adjacent second gates 1240. Additionally, a third nitride layer 1250 may be disposed between the first contact region 1223 and the second gates 1240.

A second oxide layer 1260 may be disposed over the third nitride layer 1250 located between the second gates 1240. Contact portions to which the second gates 1240 and the conductive lines are connected may be formed in the second gates 1240 using a difference in etch rate between the second oxide layer 1260 and the third nitride layer 1250.

The contact 1310 may include a metal, a metal silicide, or a metal nitride. At least a portion of the capacitor (CAP) disposed over the contact 1310 may be arranged to overlap the contact 1310.

The contact insulation layer 1270 may be disposed between adjacent first contact regions 1223.

A layer where the capacitor (CAP) is disposed may be referred to as a capacitor layer 1300.

The capacitor layer 1300 may include at least a portion of the contacts 1310, and may further include capacitors (CAPs) and a capacitor insulation layer 1320 disposed between the capacitors (CAPs).

As is apparent from the above description, the semiconductor device based on some embodiments of the present disclosure includes three-dimensional (3D) channels to improve the degree of integration.

Additionally, the semiconductor device based on some embodiments of the present disclosure can reduce contact resistance between the active region and the bit line, and can reduce contact resistance between the active region and the capacitor.

The embodiments of the present disclosure may provide a variety of effects capable of being directly or indirectly recognized through the above-mentioned patent document.

Those skilled in the art will appreciate that the present disclosure may be carried out in other specific ways than those set forth herein. In addition, claims that are not explicitly presented in the appended claims may be presented in combination as an embodiment or included as a new claim by a subsequent amendment after the application is filed.

Although a number of illustrative embodiments have been described, it should be understood that modifications and enhancements to the disclosed embodiments and other embodiments can be devised based on what is described and/or illustrated in this patent document.

What is claimed is:

1. A semiconductor device comprising:
a bit line disposed to extend in a first direction;
a first gate disposed to extend in a second direction intersecting with the first direction;
a second gate disposed to extend in parallel with the first gate;
an active region having a first side contacting the bit line; and
a contact disposed to contact a second side of the active region,
wherein the active region includes:
a horizontal portion disposed to extend in the first direction;
a vertical portion disposed between the first gate and the second gate; and a first contact region disposed to contact the contact and the vertical portion.

2. The semiconductor device according to claim 1, wherein the bit line is disposed to contact the horizontal portion.

3. The semiconductor device according to claim 1, wherein the active region further includes a second contact region disposed between the bit line and the horizontal portion to contact the bit line and the horizontal portion.

4. The semiconductor device according to claim 1, wherein the active region includes indium gallium zinc oxide (IGZO).

5. The semiconductor device according to claim 1, wherein a width of the first contact region is equal to or larger than a width of the vertical portion.

6. The semiconductor device according to claim 1, wherein a width of the first contact region is equal to or smaller than a width of the contact.

7. The semiconductor device according to claim 1, wherein the active region further includes a first extension region disposed to contact a bottom surface of the first contact region and a side surface of the vertical portion.

8. The semiconductor device according to claim 1, wherein the first contact region is disposed to contact bottom and side surfaces of the contact.

9. The semiconductor device according to claim 8, wherein the first contact region is disposed along sidewalls and a bottom surface of a contact trench disposed in a contact insulation layer.

10. The semiconductor device according to claim 9, wherein the contact trench is disposed to overlap the vertical portion.

11. The semiconductor device according to claim 1, wherein the contact is connected to a capacitor.

12. The semiconductor device according to claim 1, wherein the vertical portion extends along a side surface of the first gate, and forms a first angle with respect to the horizontal portion.

13. The semiconductor device according to claim 1, wherein the active region further includes a second extension region disposed over the horizontal portion.

14. The semiconductor device according to claim 1, wherein the first gate and second gate is configured to receive different control signals.

15. A semiconductor device comprising:
a bit line disposed to extend in a first direction;
a first gate disposed to extend in a second direction intersecting with the first direction;
one pair of second gates disposed at both sides of the first gate to extend in parallel with the first gate;
an active region having a first side contacting the bit line; and
a contact disposed to contact a second side of the active region,
wherein the active region includes:
a horizontal portion disposed to extend in the first direction and contact the bit line;
a vertical portion disposed between the first gate and the second gates to extend from the horizontal portion toward the contact; and
a first contact region disposed between the contact and the vertical portion, and
wherein the horizontal portion is located below the second gates.

16. The semiconductor device according to claim 15, wherein the active region further includes a second contact region disposed between the bit line and the horizontal portion to contact the bit line and the horizontal portion.

17. The semiconductor device according to claim 15, wherein the active region includes indium gallium zinc oxide (IGZO).

18. The semiconductor device according to claim 15, wherein the active region further includes a first extension region disposed to contact a bottom surface of the first contact region and a side surface of the vertical portion.

19. The semiconductor device according to claim 18, wherein the first extension region is disposed to contact bottom and side surfaces of the contact.

20. The semiconductor device according to claim 15, wherein the active region further includes a second extension region disposed over the horizontal portion.

21. A semiconductor device comprising:
a bit line disposed to extend in a first direction;
a first gate disposed to extend in a second direction intersecting with the first direction, wherein a cross-section of the first gate has a trapezoidal shape;
one pair of second gates disposed at both sides of the first gate to extend in parallel with the first gate; and
an active region including a horizontal portion contacting the bit line and a vertical portion disposed between the first gate and the pair of second gates to extend in a vertical direction.
